(19) United States
(12) Patent Application Publication
(10) Pub. No.: US 2008/0121992 A1
(43) Pub. Date: May 29, 2008

(54) SEMICONDUCTOR DEVICE INCLUDING DIFFUSION BARRIER REGION AND METHOD OF FABRICATING THE SAME

(75) Inventors: Ji-hye YI, Suwon-si (KR); Hwa-sung RHEE, Seongnam-si (KR); Tetsuji UENO, Suwon-si (KR); Ho LEE, Cheonan-si (KR); Myung-sun KIM, Hwaseong-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/835,551

(22) Filed: Aug. 8, 2007

(30) Foreign Application Priority Data
Nov. 29, 2006 (KR) 10-2006-0119140

(51) Int. Cl. H01L 27/092; H01L 21/8238

(52) U.S. Cl. 257/336; 438/217; 257/E21.632; 257/E27.062

(57) ABSTRACT

A semiconductor device includes a substrate having an n-type transistor region and a p-type transistor region. The n-type transistor region includes a first gate electrode, first source/drain regions located adjacent to the first gate electrode, a first channel region located between the first source/drain regions, and a first diffusion barrier region located in the first source/drain regions or in both the first channel region and the first source/drain regions. The p-type transistor region includes a second gate electrode, second source/drain regions located adjacent to the second gate electrode, a second channel region located between the second source/drain regions, and a second diffusion barrier region located in the second source/drain regions or in both the second channel region and the second source/drain regions.

### CROSS-REFERENCE TO RELATED PATENT APPLICATION

This application claims the benefit of Korean Patent Application No. 10-2006-0119140, filed on Nov. 29, 2006, the subject mater of which is hereby incorporated by reference.

### BACKGROUND OF THE INVENTION

1. Field of the Invention

The present invention relates to a semiconductor device and a method of fabrication. More particularly, the present invention relates to a semiconductor device having a diffusion barrier region on a semiconductor substrate, and a method of fabricating the same.

2. Description of the Related Art

Presently, the size of semiconductor integrated circuits is being reduced, while speed requirements are increased and power consumption requirements are decreased. Accordingly, channel lengths of transistors within the semiconductor integrated circuits must likewise be reduced. However, reduction of the transistor channel lengths causes an undesirable electrical phenomenon, known as short channel effect (SCE).

In order to prevent SCE from occurring, the channel length of a transistor must be reduced in a horizontal direction, and the thickness of a gate insulating layer or the junction length of the source/drain regions of the transistor must be reduced in a vertical direction. In other words, a shallow junction is required.

Research into shallow junctions has resulted in development of a light doped drain (LDD) structure for reducing hot carriers around drains and a halo structure for preventing depletion regions of a source and a drain from approaching each other, without affecting a doping density of a channel region. However, because the typical design rule of semiconductor devices is 50 nm or under 32 nm, for example, the LDD structure and/or the halo structure cannot alone effectively prevent SCE from occurring.

Accordingly, there is a need for a semiconductor device having a shallow junction, in which the SCE is mitigated, and a method of manufacturing such a semiconductor device.

### SUMMARY OF THE INVENTION

The present invention provides a semiconductor device having a diffusion barrier region and a fabrication method.

An aspect of the present invention provides a semiconductor device, which includes a substrate having an n-type transistor region and a p-type transistor region. The semiconductor device also includes a first gate electrode located in the n-type transistor region, first source/drain regions located adjacent to the first gate electrode in the n-type transistor region, a first channel region located between the first source/drain regions, and a first diffusion barrier region located in the first source/drain regions or in both the first channel region and the first source/drain regions. The semiconductor device further includes a second gate electrode located in the p-type transistor region, second source/drain regions located adjacent to the second gate electrode in the p-type transistor region, a second channel region located between the second source/drain regions, and a second diffusion barrier region located in the second source/drain regions or in both the second channel region and the second source/drain regions. The first and second diffusion barrier regions may include fluorine ions or carbon ions, and dose of the fluorine or carbon ions may be in a range of 5e14/cm2 to 5e15/cm2.

Each of the first source/drain regions may include a first deep source/drain region and a first light doped drain (LDD) region, and each of the second source/drain regions may include a second deep source/drain region and a second LDD region. The first diffusion barrier region may be located in the first LDD region or in the first channel region at a same depth as the first LDD region. Likewise, the second diffusion barrier region may be located in the second LDD region or in the second channel region at a same depth as the second LDD region. Furthermore, each of the first source/drain regions may further include a first halo region contacting the first deep source/drain region in a direction of the first channel region, and the first diffusion barrier region may located in the first halo region or at a same depth as the first halo region. The first LDD region and the first deep source/drain region may include arsenic or phosphorous ions, the first halo region may include boron or boron difluoride (BF2) ions, and the second LDD region and the second deep source/drain region may include boron or boron difluoride (BF2) ions.

Another aspect of the present invention provides a semiconductor device having a substrate, which has an n-type transistor region and a p-type transistor region. A first diffusion barrier region, including fluorine or carbon ions, is located in the n-type transistor region. A second diffusion barrier region, including fluorine or carbon ions, is located in the p-type transistor region. A dose of the fluorine or carbon ions may be in the range of 5e14/cm2 to 5e15/cm2. The n-type transistor region may include first source/drain regions, each of which includes a first deep source/drain region and a first LDD region, sequentially formed in the substrate, and the p-type transistor region may include second source/drain regions, each of which includes a second deep source/drain region and a second LDD region, sequentially formed in the substrate.

The first diffusion barrier region may be located in the first LDD region, and the second diffusion barrier region may be located in the second LDD region. Also, the first diffusion barrier region may be located in a first channel region, positioned between the first source/drain regions, and the second diffusion barrier region may be located in a second channel region, positioned between the second source/drain regions. Also, each of the first source/drain regions may further include a first halo region, e.g., contacting the first deep source/drain regions in the direction of the first channel region, such that the first diffusion barrier region is located in the first halo region, and/or at a same depth as the first halo region.

Yet another aspect of the present invention provides a method of fabricating a semiconductor device, including defining an active region by forming an isolation layer in a semiconductor substrate comprising an n-type transistor region and a p-type transistor region, and forming a first diffusion barrier region in the n-type transistor region and a second diffusion barrier region in the p-type transistor region by implanting fluorine or carbon ions into the active region. The method further includes forming a first gate electrode in the n-type transistor region and a second gate electrode in the p-type transistor region on the active region, and forming first source/drain regions and second source/drain regions adjacent to the first gate electrode and the second gate electrode, respectively, in the active region. A dose of the fluorine or carbon ions implanted into the active region may be 5e14/cm2 to 5e15/cm2. Also, the first diffusion barrier region and the second diffusion barrier region may be formed at the same time.

Forming each of the first source/drain regions may include sequentially forming a first deep source/drain region and an LDD region in the n-type transistor region, and forming each of the second source/drain regions may include sequentially forming a second deep source/drain region and a second LDD region in the p-type transistor region. The first diffusion barrier region may be formed at least in part in the first LDD region, and the second diffusion barrier region is formed at least in part in the second LDD region. Also, forming each of the first source/drain regions may further include forming a first halo region contacting the first deep source/drain region. The first diffusion barrier region may formed in the n-type transistor region at a depth of the first halo region.

The semiconductor device according to the above embodiments of the present invention and integrated circuits to which the above manufacturing method is applied may include minute electronic devices, such as a highly integrated semiconductor device, a processor, a micro-electromechanical systems (MEMS) device, an optoelectric device, and a display device.

### BRIEF DESCRIPTION OF THE DRAWINGS

The embodiments of the present invention will be described with reference to the attached drawings, in which:

FIG. 1 is a cross-sectional view of a semiconductor device according to an embodiment of the present invention;

FIG. 2 is a cross-sectional view of a semiconductor device according to another embodiment of the present invention;

FIGS. 3A through 3F are cross-sectional views illustrating a method of manufacturing the semiconductor device of FIG. 1, according to an embodiment of the present invention;

FIGS. 4A through 4D are cross-sectional views illustrating a method of manufacturing the semiconductor device of FIG. 2, according to an embodiment of the present invention;

FIGS. 5A and 5B are graphs illustrating a threshold voltage relative to a channel length of an n-FET and a p-FET, according to embodiments of the present invention; and

FIGS. 6A and 6B are graphs illustrating on-current characteristics relative to off-current characteristics of the n-FET and the p-FET, according to embodiments of the present invention.

### DETAILED DESCRIPTION OF THE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

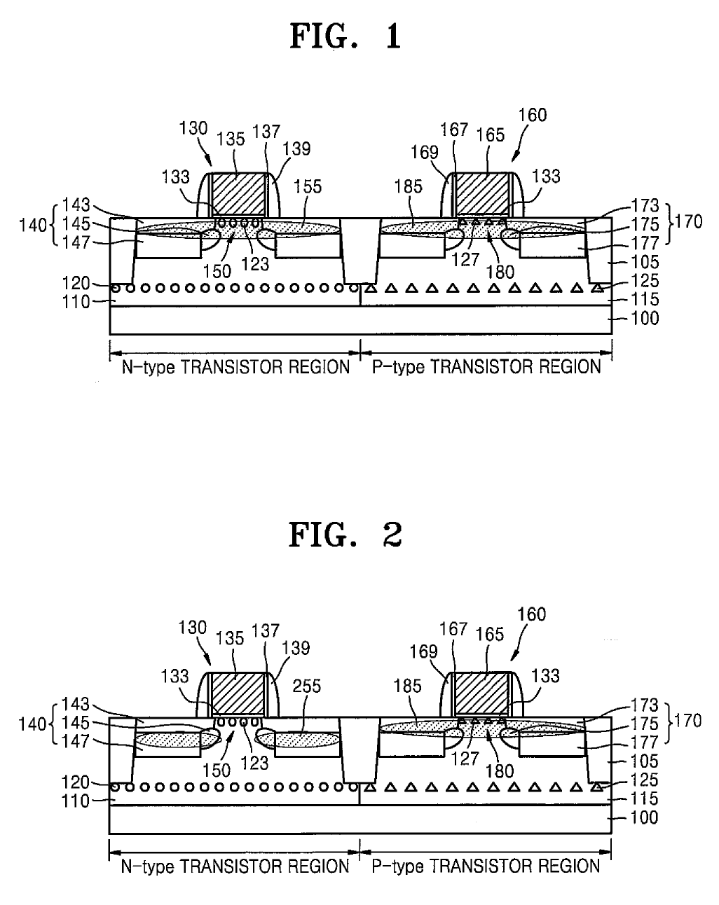

FIG. 1 is a cross-sectional view of a semiconductor device according to an embodiment of the present invention. A semiconductor substrate 100 is shown as having an n-type transistor region and a p-type transistor region. The semiconductor substrate 100 may be a p-type semiconductor substrate, for example.

An isolation layer 105 for defining an active region is formed in the semiconductor substrate 100. The isolation layer 105 may be formed using various methods and materials, such as a shallow trench isolation (STI) method. Also, a P-well 110, defining the n-type transistor region, and an N-well 115, defining the p-type transistor region, are formed in the semiconductor substrate 100. For example, if the semiconductor substrate 100 is a p-type substrate, the N-well 115 may be formed from ions, such as arsenic or phosphorous ions, in order to define the p-type transistor region.

First and second field implanting regions 120 and 125 may be formed in the semiconductor substrate 100 in order to prevent conduction around the isolation layer 105. For example, the first field implanting region 120 in the n-type transistor region may be formed from implanted boron ions, and the second field implanting region 125 in the p-type transistor region may be formed from implanted phosphorous ions. Also, first and second channel doping regions 123 and 127 may be respectively formed in the n-type and p-type transistor regions to control a threshold voltage Vₜₕ. The first channel doping region 123 may be formed from boron, for example, and the second channel doping region 127 may be formed from arsenic or phosphorous, for example.

Referring to FIG. 1, a first gate structure 130 is formed on the semiconductor substrate 100 in the n-type transistor region. The first gate structure 130 may include a gate insulating layer 133, a first gate electrode 135, a first offset spacer 137, and a first gate spacer 139.

First source/drain regions 140 are formed in the semiconductor substrate 100 and arranged adjacent to the first gate electrode 135. Each of the first source/drain regions 140 may include a first deep source/drain region 147 and a first light doped drain (LDD) region 143, which may be sequentially formed in the semiconductor substrate 100. The first source/drain regions 140 may be adjacent to each other in a direction of a first channel 123. Also, each of the first source/drain regions 140 may include a first halo region 145. In an embodiment, the first halo region 145 may contact the first deep source/drain region 147 in a direction of a first channel region 150, discussed below.

The first LDD region 143 may be formed, for example, from arsenic or phosphorous at a depth of about 50 nm or less, and the first halo region 145 may be formed, for example, from boron or boron difluoride (BF2) at a depth of about 5 to 10 nm from the surface of the semiconductor substrate 100, based on the projection range Rₚ. Also, the first deep source/drain region 147 may be formed, for example, from phosphorous at a depth of about 40 nm or from arsenic at a depth of about 25 nm, based on the projection range Rₚ. However, the depth and dose of the first source/drain regions 140 can be varied to account for the particular characteristics of the semiconductor device, without departing from the spirit and scope of the present invention.

A first channel region 150 is formed in the semiconductor substrate 100 between the first source/drain regions 140 under the first gate electrode 135. The first source/drain region 140 shown located at the left side of the first gate electrode 135 may be a first source region, and the first source/drain region 140 shown located at the right side of the first gate electrode 135 may be a first drain region. However, the present invention is not limited to this arrangement, and thus the first source/drain region 140 at the left side of the first gate electrode 135 may alternatively be a first drain region and the first source/drain region 140 on the right side of the first gate electrode 135 may be a first source region.

A first diffusion barrier region 155 may be formed in the first channel region 150 or in the first LDD region 143. Also, the first diffusion barrier region 155 may be further formed in the first LDD region 143. For example, the first diffusion barrier region 155 may be formed in the first channel region 150 at the same depth as the first LDD region 143. The first diffusion barrier region 155 may be formed, for example, from fluorine or carbon, having an implant dose of about 5e¹⁴/cm² to 5e¹⁵/cm².

When the first LDD region 143 is formed, for example, from phosphorous, the first diffusion barrier region 155 reduces or prevents the diffusion or penetration of phosphorous ions into a channel of the n-type transistor region in a horizontal direction. Thus a potential short channel effect (SCE) is mitigated or prevented altogether.

Referring again to FIG. 1, a second gate structure 160 is formed on the semiconductor substrate 100 in the p-type transistor region. The second gate structure 160 may include a gate insulating layer 133, a second gate electrode 165, second offset spacers 167, and second gate spacers 169. In alternative embodiments, the gate insulating layer 133 may be the same as or different from the gate insulating layer 133 of the first gate structure 130.

Second source/drain regions 170 are arranged adjacent to the second first gate electrode 165 and formed in the semiconductor substrate 100. Each of the second source/drain regions 170 may include a second deep source/drain region 177 and a second LDD region 173, which may be sequentially formed in the semiconductor substrate 100. The second source/drain regions 170 may be adjacent to each other in a direction of a second channel 127. Each of the second source/drain regions 170 may further include a second halo region 175.

The second LDD region 173 may be formed, for example, from boron or boron difluoride (BF₂) at a depth of about 5 nm or less relative to the surface of the semiconductor substrate 100, and the second halo region 175 may be formed, for example, from arsenic or phosphorous at a depth of about 5 to 10 nm from the surface of the substrate 100, based on a projection range Rₚ. Also, the second deep source/drain regions 177 may be formed, for example, from boron at a depth of about 25 nm based on the projection range Rₚ. Of course, the depth and dose of the second source/drain regions 170 can be varied to account for the particular characteristics of the semiconductor device, without departing from the spirit and scope of the present invention.

A second channel region 180 is formed in the semiconductor substrate 100 between the second source/drain regions 170 under the second gate electrode 165. The second source/drain region 170 shown on the left side of the second gate electrode 165 may be a second source region, and the second source/drain region 170 on the right side of the second gate electrode 165 may be a second drain region However, the present invention is not limited to this arrangement, and thus the second source/drain region 170 on the left side of the second gate electrode 165 may alternatively be a second drain region, and the second source/drain region 170 on the right side of the second gate electrode 165 may be a second source region

A second diffusion barrier region 185 may be formed in the second channel region 180. Also, the second diffusion barrier region 185 may be further formed in the second LDD region 173. For example, the second diffusion barrier region 185 may be formed in the second channel region 180 at the same depth as the second LDD region 173. The second diffusion barrier region 185 may be formed, for example, from fluorine or carbon, having an implant dose of about 5e¹⁴/cm² to 5e¹⁵/cm².

When the second LDD region 173 is formed from phosphorous, for example, the second diffusion barrier region 185 effectively reduces or prevents the diffusion or penetration of boron or boron difluoride ions into a channel of the p-type transistor region in a horizontal direction. Thus a potential short channel effect (SCE) is mitigated or prevented altogether.

According to the embodiment described above, the first diffusion barrier region 155 and the second diffusion barrier region 185 are located in the channels of the n-type and p-type transistor regions, respectively, in order to mitigate or prevent SCE.

FIG. 2 is a cross-sectional view of a semiconductor device according to another embodiment of the present invention. The semiconductor device of FIG. 2 is substantially the same as the semiconductor device of FIG. 1, except for the position of the diffusion barrier region (e.g., the first diffusion barrier region 155). Therefore, because like elements are denoted with like reference numerals, descriptions of the like elements of FIG. 2 will not be repeated.

Referring to FIG. 2, a third diffusion barrier region 255 is formed in the first halo region 145 of each of the first source/drain regions 140. Also, the third diffusion barrier region 255 may be formed in the first channel region 150 at the same depth as the first halo region 145, if necessary. The third diffusion barrier region 255 may be formed, for example, from fluorine or carbon, having an implant dose of about 5e¹⁴ cm²to about 5e¹⁵/cm².

The third diffusion barrier region 255 effectively reduces or prevents the diffusion or penetration of boron or boron difluoride ions into a channel of the n-type transistor region in a horizontal direction. Thus a potential short channel effect (SCE) is mitigated or prevented altogether.

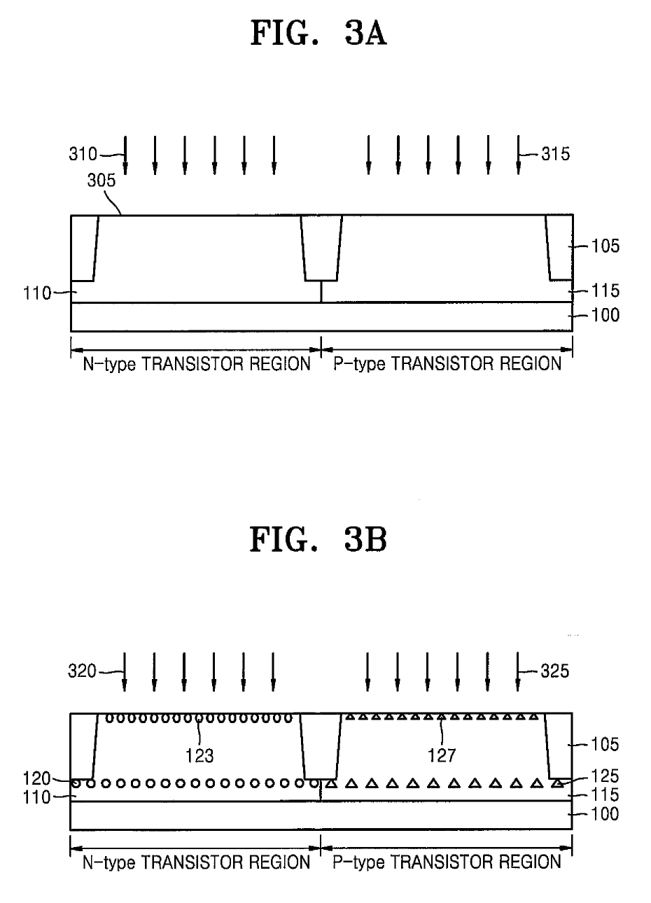

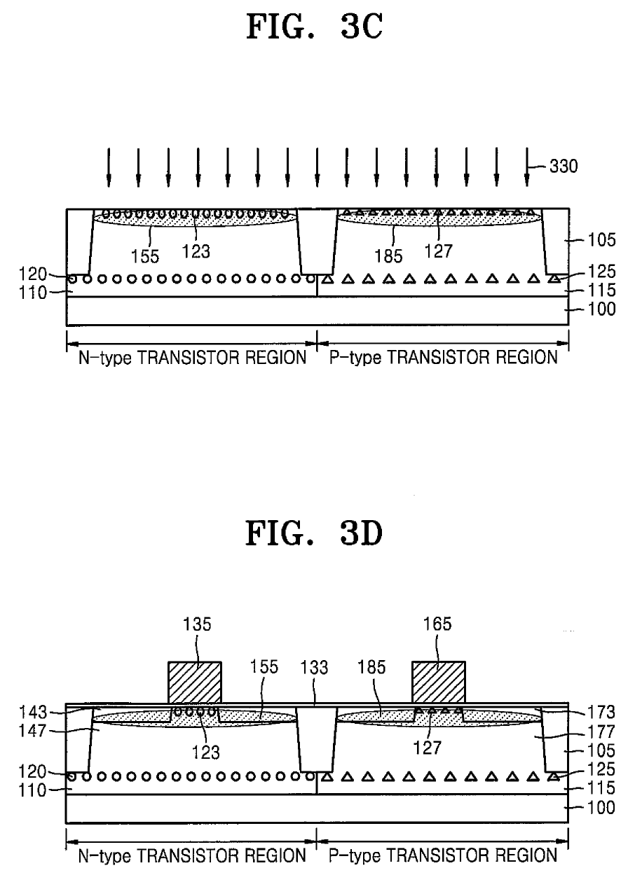

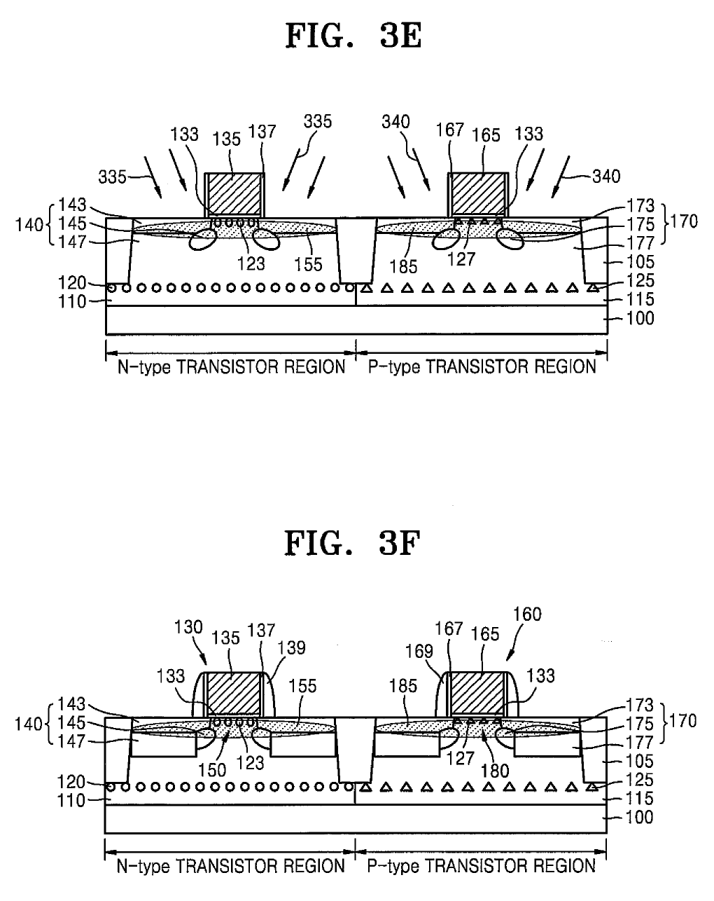

FIGS. 3A through 3F are cross-sectional views illustrating a method of fabricating the exemplary semiconductor device depicted in FIG. 1. Referring to FIG. 3A, the semiconductor substrate 100 is formed, having an n-type transistor region and a p-type transistor region. The isolation layer 105 is formed in the semiconductor substrate 100 to define an active region 305, in which a transistor and other elements may be formed. The isolation layer 105 can be formed using various methods and materials, including, for example, an STI method, without departing from the spirit and scope of the present invention.

Next, the P-well 110 is formed in the semiconductor substrate 100 to define the n-type transistor region. For example, the P-well 110 may be formed by implanting boron ions 310 using an energy of about 180 keV to about 280 keV. The N-well 115 is formed in the semiconductor substrate 100 to define a p-type transistor region. For example, the N-well 115 may be formed from arsenic or phosphorous ions using an energy of about 300 keV to about 400 keV. In the present embodiment, the P-well 110 and the N-well 115 may optionally be formed according to specifications.

Referring to FIG. 3B, the first implanting region 120 and second implanting region 125 are formed to prevent conduction around the isolation layer 105, and the first channel doping region 123 and second channel doping region 127 are formed to control a threshold voltage Vₜₕ. The first implanting region 120 and the first channel doping region 123, which are located in the n-type transistor region, are formed by implanting boron or boron difluoride 320. For example, the p-type transistor region may be covered by a mask (not shown), and the dose and energy of the boron or boron difluoride 320 are changed in order to form the first implanting region 120 and the first channel doping region 123. Similarly, the second implanting region 125 and the second channel doping region 127, which are located in the p-type transistor region, are formed by implanting arsenic or phosphorous ions 325. For example, the n-type transistor region may be covered with a mask (not shown), and the dose and energy of the arsenic or phosphorous ions 325 are changed to form the second implanting region 125 and the second channel doping region 127.

Referring to FIG. 3C, the first diffusion barrier region 155 in the n-type transistor region and the second diffusion barrier region 185 in the p-type transistor region are respectively formed in the channel regions of the n-type and p-type transistor regions by implanting fluorine or carbon ions 330 in the active region 305. In an embodiment, the first and second diffusion barrier regions 155 and 185 are formed at the same time. The dose of fluorine or carbon ions 330 may be, for example, about 5e¹⁴/cm² to about 5e¹⁵/cm². Also, the depth of the first second diffusion barrier region 155 and the second diffusion barrier region 185 can be controlled by varying the ion implant energy of the fluorine or carbon ions 330 when the first and second diffusion barrier regions 155 and 185 are formed.

Referring to FIG. 3D, the gate insulating layer 133, the first gate electrode 135, and the second gate electrode 165 are formed on the semiconductor substrate 100. The gate insulating layer 133 may be, for example, a thin oxide insulating layer or a high-K oxide insulating layer, according to specifications. Also, the gate insulating layer 133 may be used separately for each of the n-type and p-type transistors according to the respective characteristics of the n-type and p-type transistors. Also, the first gate electrode 135 and the second gate electrode 165 may be formed from a polysilicon layer, a metal layer or a metal nitride layer.

Then, the first and second LDD regions 143 and 173 are formed on the first and second gate electrodes 135 and 165, respectively. The first LDD region 143 may be formed, for example, from arsenic or phosphorous ions 325 at a depth of about 5 nm or less, based on the projection range Rₚ, and the second LDD region 173 may be formed, for example, from boron or boron difluoride (BF₂) at a depth of about 5 nm or less, based on the projection range Rₚ.

Referring to FIG. 3E, the first offset spacer 137 and the second offset spacer 167 are formed on the first gate electrode 135 and second gate electrode 165, respectively. The first and second offset spacers 137 and 167 secure a distance between the first and second electrodes 135 and 165, and in an embodiment, may be formed before formation of the first and second LDD regions 143 and 173 depicted in FIG. 3D. Then, the first halo region 145 is formed by implanting boron 335, for example, at a depth of about 5 to 10 nm, based on the projection range Rₚ. Also, the second halo region 175 may be formed by implanting arsenic 340, for example, at a depth of about 5 to 10 nm.

Referring to FIG. 3F, the first and second gate spacers 139 and 169 are formed on the first and second gate electrodes 135 and 165, respectively. Alternatively, the first and second gate spacers 139 and 169 may be formed on the first and second offset spacers 137 and 167, respectively. Then, the first and second deep source/drain regions 147 and 177 are formed, respectively located adjacent to either the first and second gate structures 130 and 160 or the first and second gate electrodes 135 and 165. The first and second deep source/drain regions 147 and 177 may be formed using the first and second gate structures 130 and 160 as a mask. The first deep source/drain regions 147 may be formed, for example, at a depth of about 40 nm when the first deep source/drain regions 147 are formed from phosphorous ions, or at a depth of about 25 nm, for example, when the first deep source/drain regions 147 are formed from arsenic based on the projection range Rₚ. Also, the second deep source/drain regions 177 may be formed, for example, at a depth of about 25 nm when the second deep source/drain regions 177 are formed from boron based on the projection range Rₚ. However, the depth and dose of the first and second source/drain regions 147 and 177 can be varied to account for the particular characteristics of the semiconductor device, without departing from the spirit and scope of the present invention.

Then, the first and second source/drain regions 140 and 170 are heated to be activated. For example, the heat treatment of the first and second source/drain regions 140 and 170 may be a spike annealing process performed rapidly at a high temperature, such as 1000° C. or higher.

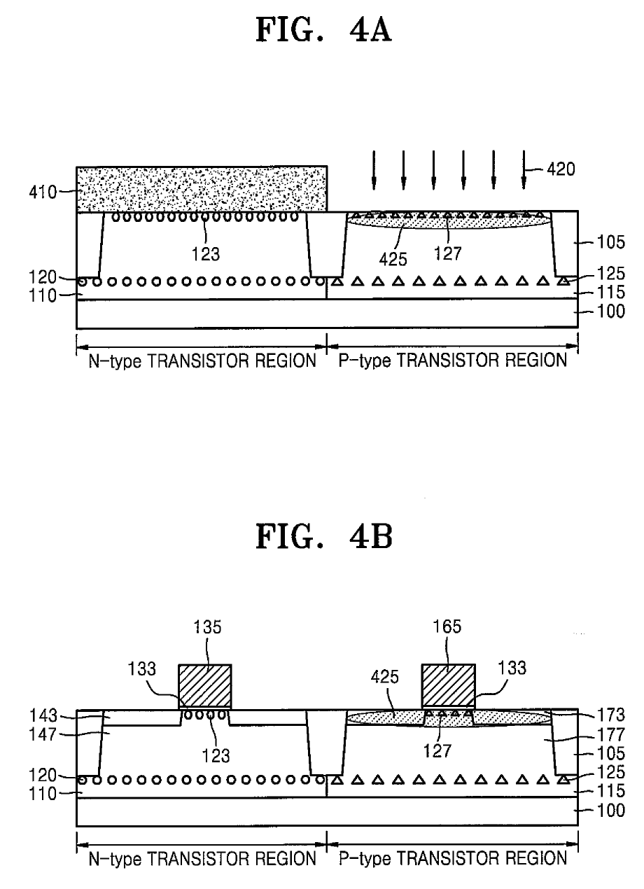

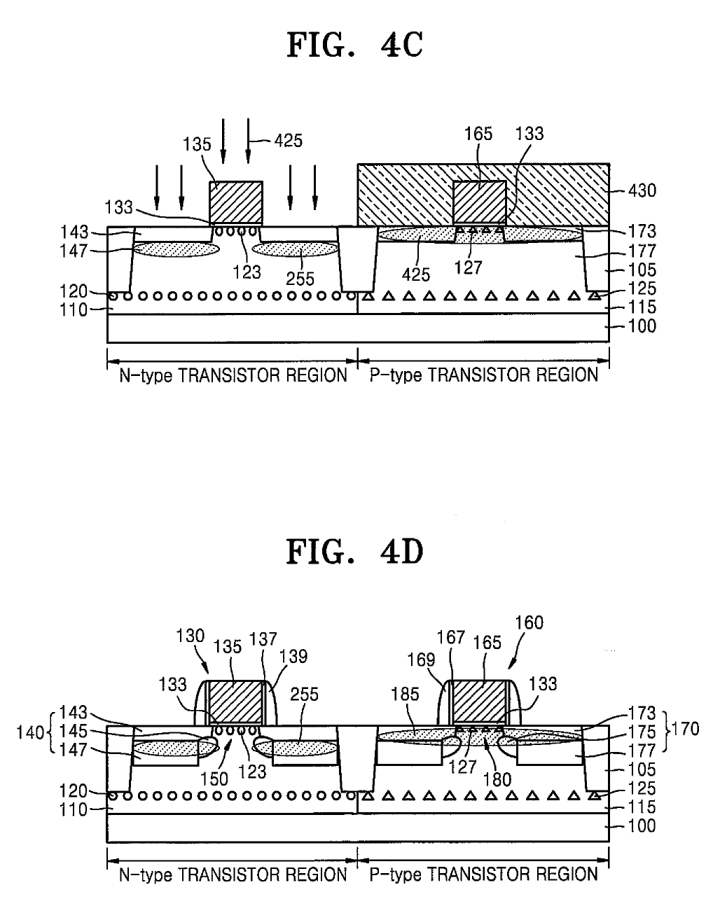

FIGS. 4A through 4D are cross-sectional views illustrating a method of fabricating the semiconductor device of FIG. 2, according to another embodiment of the present invention. The semiconductor device of FIG. 2 is substantially identical to the semiconductor device of FIG. 1, except for the position of the diffusion barrier region (e.g., the first diffusion barrier region 155). Therefore, because like elements are denoted with like reference numerals, descriptions of the like elements of FIG. 2, as well as FIG. 3A to FIG. 3F, will not be repeated.

Referring to FIG. 4A, an isolation layer 105, a P-well 110, an N-well 115, first and second implanting regions 120 and 125, and first and second channel doping regions 123 and 127 are formed on the semiconductor substrate in the n-type and p-type transistor regions, as described above. In addition, a first mask 410 is formed on the n-type transistor region. Then, a second diffusion barrier region 425 is formed by implanting fluorine or carbon ions 420 in the semiconductor substrate 100 in the p-type transistor region using the first mask 410. The dose of the fluorine or carbon ions may be, for example, about 5e¹⁴/cm² to about 5e¹⁵/cm².

Referring to FIG. 4B, a gate insulating layer 133, a first gate electrode 135, and a second gate electrode 165 are formed on the semiconductor substrate 100. The gate insulating layer 133 may be a thin oxide insulating layer or a high-K oxide insulating layer, according to specifications. Also, the gate insulating layer 133 can be used separately for each of the n-type and p-type transistors, according to the respective characteristics of the n-type and p-type transistors. Also, the first gate electrode 135 and the second gate electrode 165 may be formed from a polysilicon layer, a metal layer or a metal nitride layer.

Next, the first LDD region 143 and the second LDD region 173 are formed adjacent to the first gate electrode 135 and the second gate electrode 165, respectively. The first LDD region 143 may be formed from arsenic or phosphorous at a depth of about 5 nm or less, based on the projection range Rₚ, and the second LDD region 173 may be formed from boron or boron difluoride at a depth of about 5 nm or less, based on the projection range Rₚ.

Referring to FIG. 4C, a second mask 430 is formed on the p-type transistor region. A third diffusion barrier region 255 is formed using the second mask 430 by implanting fluorine or carbon ions 425 into the n-type transistor region of the substrate. The dose of fluorine or carbon ions 425 may be, for example, from 5e¹⁴1cm² to 5e¹⁵/cm². In an embodiment, the third diffusion barrier region 255 may be formed under the first LDD region 143, that is, at the same depth as of the first halo region 145.

Referring to FIG. 4D, the first and second offset spacers 137 and 167 are respectively formed on the first and second gate electrodes 135 and 165. The first and second halo regions 145 and 175 are formed, either before or after the forming of the third diffusion barrier region 255. The first and second gate spacers 139 and 169 are respectively formed on the first and second gate electrodes 135 and 165, or alternatively on the first and second offset spacers 137 and 167. The first and second deep source/drain regions 147 and 177, respectively located adjacent to the first and second gate structures 130 and 160 or the first and second gate electrodes 135 and 165, are formed using the first and second gate structures 130 and 160 as a mask.

According to the fabrication method described above, the third diffusion barrier region 255 of the semiconductor device of FIG. 2 effectively reduces or prevents a diffusion or penetration of the material of the first halo region 145 (e.g., boron ions) into a channel of the n-type transistor region in a horizontal direction. Thus, a potential short channel effect (SCE) is mitigated or prevented altogether.

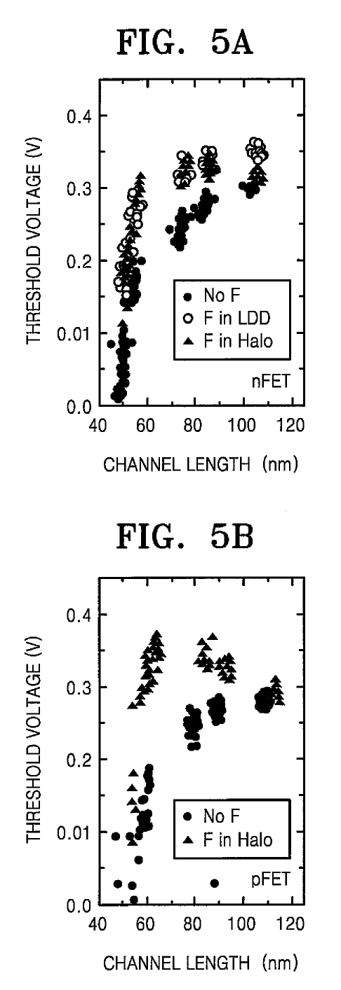

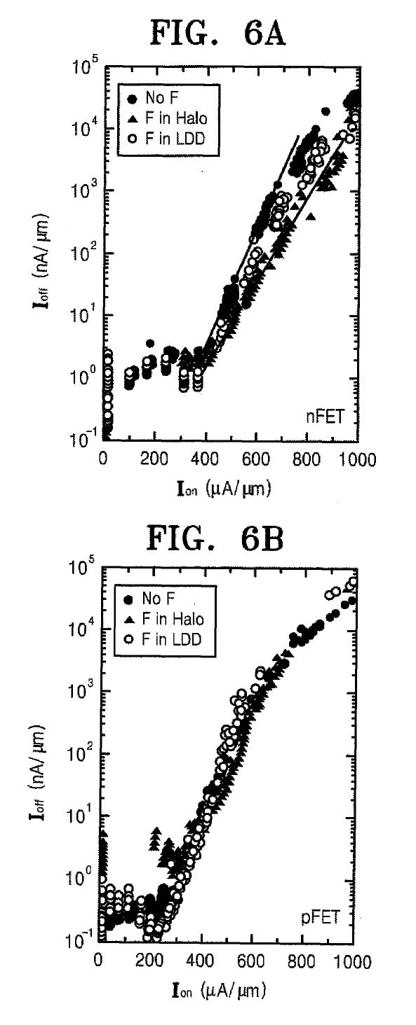

FIGS. 5A and 5B are graphs depicting threshold voltages in relation to the channel length of an n-FET and a p-FET, respectively, of the semiconductor device according to embodiments of the present invention. FIGS. 6A and 6B are graphs depicting on-current versus off-current of the n-FET and p-FET, respectively, of the semiconductor device according to embodiments of the present invention. In each of the graphs, the symbol ▴ denotes a state with no diffusion barrier region, the symbol ∘ denotes a state with a diffusion barrier region located in an LDD region (e.g., first and second diffusion barrier regions), and the symbol ▴ denotes a state with a diffusion barrier region located in a halo region (e.g., third diffusion barrier region). The diffusion barrier regions, the characteristics off which are depicted in graphs of FIGS. 5A, 5B, 6A and 6B, may be doped with fluorine.

Referring to FIGS. 5A and 5B, when a semiconductor device includes a diffusion barrier region (∘, ▴), the transistor channel length is less than the channel length of a semiconductor device without a diffusion barrier region (), thus mitigating SCE and improving performance. For example, in the case of the n-FET (FIG. 5A), for a channel length of 80 nm, when the first diffusion barrier region 155 of the first LDD region 143 (see FIG. 1) or the third diffusion barrier region 255 of the first halo region 145 (see FIG. 2) are included in the n-type transistor region, the threshold voltage is 0.3 to 0.35 V. However, when there is no first or third diffusion barrier region present, the threshold voltage is only 0.25 to 0.3 V for the same channel length. In other words, the threshold voltage decreases less with corresponding decreases in channel length when a diffusion barrier region is present, as compared to when a diffusion barrier region is not present.

This is also evident with respect to performance of the p-FET (FIG. 5B), when the second diffusion barrier region 185 is included in the p-type transistor region of the semiconductor device. For example, the threshold voltages are higher for the channel length of 60 nm when the second diffusion barrier region 185 is included, as compared to the same channel length with no diffusion barrier region.

Referring to FIGS. 6A and 6B, when a semiconductor device includes a diffusion barrier region (▴, ∘,), an on-current Iₒₙ is increased by 3 to 5 percent without a decrease in an off-current I_{off} characteristic, as compared to when no diffusion barrier region is present (). For example, when the off-current I_{off} is 10² nA/μm, the on-current Iₒₙ of the n-FET having a diffusion barrier region (e.g., the first diffusion barrier region 155 or the third diffusion barrier region 255) is about 600 to 680 μA/μm. However, the on-current Iₒₙ of the n-FET having no diffusion barrier region is only about 560 μA/μm. The relationship between the off-current I_{off} and the on-current Iₒₙ of the p-FET having a diffusion barrier region (e.g., the second diffusion barrier region 185) is the similar, as shown in FIG. 6B. Accordingly, FIGS. 6A and 6B further show that SCE is mitigated in n-type and p-type transistors when diffusion barrier regions are formed, in accordance with embodiments of the present invention, without negatively affecting the characteristics of the off-current i_{off}.

As described above, according to embodiments of the present invention, a semiconductor device and a method of fabricating the semiconductor device mitigates or prevents SEC based on the formation of a diffusion barrier region in an n-type transistor and/or a p-type transistor.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A semiconductor device comprising:
a substrate comprising an n-type transistor region and a p-type transistor region;
a first gate electrode located in the n-type transistor region;
first source/drain regions located adjacent to the first gate electrode in the n-type transistor region;
a first channel region located between the first source/drain regions;
a first diffusion barrier region located in the first source/drain regions or in both the first channel region and the first source/drain regions;
a second gate electrode located in the p-type transistor region;
second source/drain regions located adjacent to the second gate electrode in the p-type transistor region;
a second channel region located between the second source/drain regions; and
a second diffusion barrier region located in the second source/drain regions or in both the second channel region and the second source/drain regions.

2. The semiconductor device of claim 1, wherein the first and second diffusion barrier regions comprise fluorine ions or carbon ions.

3. The semiconductor device of claim 2, wherein each of the first source/drain regions comprises a first deep source/drain region and a first light doped drain (LDD) region; and wherein each of the second source/drain regions comprises a second deep source/drain region and a second LDD region.

4. The semiconductor device of claim 3, wherein the first diffusion barrier region is located in the first LDD region or in the first channel region at a same depth as the first LDD region.

5. The semiconductor device of claim 3, wherein the second diffusion barrier region is located in the second LDD region or in the second channel region at a same depth as the second LDD region.

6. The semiconductor device of claim 3, wherein each of the first source/drain regions further comprises a first halo region contacting the first deep source/drain region in a direction of the first channel region.

7. The semiconductor device of claim 6, wherein the first diffusion barrier region is located in the first halo region or at a same depth as the first halo region.

8. The semiconductor device of claim 2, wherein a dose of the fluorine or carbon ions in the first and second diffusion barrier regions is in a range of 5e¹⁴/cm² to 5e¹⁵/cm².

9. The semiconductor device of claim 7, wherein a dose of the fluorine or carbon ions in the first and second diffusion barrier regions is in a range of 5e¹⁴/cm² to 5e¹⁵/cm².

10. The semiconductor device of claim 7, wherein the first LDD region and the first deep source/drain region comprise arsenic or phosphorous ions, the first halo region comprises boron or boron difluoride (BF₂) ions, and the second LDD region and the second deep source/drain region comprise boron or boron difluoride (BF₂) ions.

11. A semiconductor device comprising:
a substrate comprising an n-type transistor region and a p-type transistor region; and
a first diffusion barrier region located in the n-type transistor region, the first diffusion barrier region comprising fluorine or carbon ions.

12. The semiconductor device of claim 11, further comprising:
a second diffusion barrier region located in the p-type transistor region, the second diffusion barrier region comprising fluorine or carbon ions.

13. The semiconductor device of claim 12, wherein the n-type transistor region comprises first source/drain regions, each of the first source/drain regions comprising a first deep source/drain region and a first LDD region, sequentially formed in the substrate; and
wherein the p-type transistor region comprises second source/drain regions, each of the second source/drain regions comprising a second deep source/drain region and a second LDD region, sequentially formed in the substrate.

14. The semiconductor device of claim 13, wherein the first diffusion barrier region is located in the first LDD region, and the second diffusion barrier region is located in the second LDD region.

15. The semiconductor device of claim 13, further comprising:
a first channel region located between the first source/drain regions; and
a second channel region located between the second source/drain regions.

16. The semiconductor device of claim 15, wherein the first diffusion barrier region is located in the first channel region, and the second diffusion barrier region is located in the second channel region.

17. The semiconductor device of claim 15, wherein each of the first source/drain regions further comprise a first halo region contacting the first deep source/drain regions in the direction of the first channel region.

18. The semiconductor device of claim 17, wherein the first diffusion barrier region is located in the first halo region.

19. The semiconductor device of claim 17, wherein the first diffusion barrier region is located at a same depth as the first halo region.

20. The semiconductor device of claim 11, wherein a dose of the fluorine or carbon ions of the first diffusion barrier region is 5e¹⁴/cm² to 5e¹⁵/cm².

21. The semiconductor device of claim 12, wherein a dose of the fluorine or carbon ions of the second diffusion barrier region is 5e¹⁴/cm² to 5e15/cm².

22. A method of fabricating a semiconductor device, the method comprising:
defining an active region by forming an isolation layer in a semiconductor substrate comprising an n-type transistor region and a p-type transistor region;
forming a first diffusion barrier region in the n-type transistor region and a second diffusion barrier region in the p-type transistor region by implanting fluorine or carbon ions into the active region;
forming a first gate electrode in the n-type transistor region and a second gate electrode in the p-type transistor region on the active region; and
forming first source/drain regions and second source/drain regions adjacent to the first gate electrode and the second gate electrode, respectively, in the active region.

23. The method of claim 22, wherein a dose of the fluorine or carbon ions implanted into the active region is 5e¹⁴/cm² to 5e¹⁵/cm².

24. The method of claim 22, wherein the first diffusion barrier region and the second diffusion barrier region are formed at the same time.

25. The method of claim 22, wherein forming each of the first source/drain regions comprises sequentially forming a first deep source/drain region and a first light doped drain (LDD) region in the n-type transistor region, and wherein forming each of the second source/drain regions comprises sequentially forming a second deep source/drain region and a second LDD region in the p-type transistor region.

26. The method of claim 25, wherein the first diffusion barrier region is formed at least in part in the first LDD region, and the second diffusion barrier region is formed at least in part in the second LDD region.

27. The method of claim 22, wherein forming each of the first source/drain regions further comprises forming a first halo region contacting the first deep source/drain region.

28. The method of claim 27, wherein the first diffusion barrier region is formed in the n-type transistor region at a depth of the first halo region.
